(19) United States
(12) Patent Application Publication
(10) Pub. No.: US 2021/0049122 A1
(43) Pub. Date: Feb. 18, 2021

(54) MULTI PORTED ASIC FUNCTIONAL BLOCKS TO ENABLE SETUP AND HOLD TIMING CONVERGENCE FOR MULTIPLY INSTANTIATED FUNCTIONAL BLOCKS

(71) Applicant: HEWLETT PACKARD ENTERPRISE DEVELOPMENT LP, Houston, TX (US)

(72) Inventors: Paul Armstrong, Fort Collins, CO (US); Scott Beeker, Fort Collins, CO (US); Jacquelyn M. Ingemi, Fort Collins, CO (US); David P. Hannum, Fort Collins, CO (US)

(21) Appl. No.: 16/540,175

(22) Filed: Aug. 14, 2019

(51) Int. Cl. G06F 13/40; H03K 19/177

(52) U.S. Cl. CPC G06F 13/4022; H03K 19/20; H03K 19/17724

(57) ABSTRACT

An ASIC is disclosed that is formed on a die with multiple functional blocks distributed on the die, each functional block being able to send and to receive data, and each having two inputs labeled slow and fast. The slow input may have a delay component that creates a delay in receiving a data signal, and the fast input may have less delay than the slow input. A switch may be used to couple the slow input and the fast input of a receiving functional block to a data signal based on a distance of the receiving functional block from a sending functional block. The delay in the slow input is used to adjust input data timing to meet setup and hold timing specifications of the functional blocks without altering the ASIC circuit components aside from the functional blocks.

### BACKGROUND

An application-specific integrated circuit (ASIC) is used to optimize processing hardware for a specific application. The hardware may include preprogrammed memory, built-in communication protocols, specialized data and control interfaces, hardware-assisted data processing and algorithm implementation, and the like usable to control a specialized function, machine, or process. An ASIC may include replicated functional blocks, each performing the same function. Thus, a functional block is a structural element of a portion of the ASIC.

### BRIEF DESCRIPTION OF THE DRAWINGS

The present disclosure is best understood from the following detailed description when read with the accompanying Figures. It is emphasized that, in accordance with the standard practice in the industry, various features are not drawn to scale. In fact, the dimensions of the various features may be arbitrarily increased or reduced for clarity of discussion.

FIG. 1 is an ASIC computing environment with multiple replicated functional blocks and input and output circuitry according to one or more examples of the disclosure.

FIG. 2 depicts a timing diagram showing setup and hold timing for a functional block of the ASIC of FIG. 1, according to one or more examples of the disclosure.

FIG. 3 depicts a subset of the functional blocks of the ASIC of FIG. 1 sending and receiving data according to one or more examples of the disclosure.

FIG. 4 depicts a connectivity configuration of the multiple functional blocks of the ASIC of FIG. 1 according to one or more examples of the disclosure.

FIG. 5 is a flowchart depicting a method of adjusting signal delay for setup and hold timing for the multiple functional blocks of the ASIC of FIG. 1 according to one or more examples of the disclosure.

### DETAILED DESCRIPTION

Illustrative examples of the subject matter claimed below will now be disclosed. In the interest of clarity, not all features of an actual implementation are described in this specification. It will be appreciated that in the development of any such actual implementation, numerous implementation-specific decisions may be made to achieve the developers' specific goals, such as compliance with system-related and business-related constraints, which will vary from one implementation to another. Moreover, it will be appreciated that such a development effort, even if complex and time-consuming, would be a routine undertaking for those of ordinary skill in the art having the benefit of this disclosure.

Further, as used herein, the article “a” is intended to have its ordinary meaning in the patent arts, namely “one or more.” Herein, the terms “about” and “approximately” when applied to a value generally means within the tolerance range of the equipment used to produce the value, or in some examples, means plus or minus 10%, or plus or minus 5%, or plus or minus 1%, unless otherwise expressly specified. Further, herein the term “substantially” as used herein means a majority, or almost all, or all, or an amount with a range of about 51% to about 100%, for example. The term “coupled,” as used herein, is defined as connected, whether directly without any intervening elements or indirectly with at least one intervening elements, unless otherwise indicated. Two elements may be coupled mechanically, electrically, or communicatively linked through a communication channel, pathway, network, or system. The term “and/or” as used herein refers to and encompasses any and all possible combinations of the associated listed items. Moreover, examples herein are intended to be illustrative only and are presented for discussion purposes and not by way of limitation.

As briefly noted above, ASICs are used in many applications for cost reduction, performance, and customization. ASICs may implement many functions in hardware to allow faster processing of signals and data. ASICs can also run software to add flexibility.

ASICs are generally hardware-centric and most of their functionality is implemented in hardware to improve performance and processing speed, security, reliability and cost and time for development for some applications, such as embedded applications. In accordance with this disclosure, an ASIC may have multiple functional blocks that are replications of each other. These functional blocks are also referred to as intellectual property (IP) blocks.

A functional block is a collection of circuit components and/or circuits that, together as a collaborative unit, perform a particular function. For example, a graphics functional block may receive, as input, rendering vectors and produce, as output, coordinate points on a display screen. Using hardware functional blocks, such as those in an ASIC, can perform fast graphic rendering for real-time applications, for instance. Several functional blocks of the ASIC may collaborate, for example, each rendering a predefined portion of the screen, such as a quadrant, and together render the whole screen in parallel.

Like other clock-driven digital circuits, the functional blocks have setup and hold timing specifications that are met for successful data transfers in and out of the IP block. The setup and hold timing includes time intervals just before and just after a clock signal trigger edge on which data transfer occurs.

An ASIC is fabricated on a die. A die is a semiconductor piece or substrate cut from a larger semiconductor wafer, usually made of silicon (or other semiconducting material) on which an integrated circuit (IC) has been created using the appropriate manufacturing processes, such as photolithography. The scope or extent of the IC on a die is predefined by the designer of the IC as one electronic product, such as a processor, which may actually contain many other smaller circuits or functional units, such as arithmetic logic unit (ALU), shift registers, and the like.

When multiple functional blocks are used in an ASIC, they are distributed over the die area and the physical distance between the functional blocks may affect electrical signal propagation time between the various functional blocks. In the process of designing an ASIC that includes several physical instances of the same functional block, it may not be possible to meet all the timing requirements for every instance of functional blocks to achieve the desired operational frequency for the ASIC. In designs, such as tiled switch design, in which several of the same functional blocks are tiled together, the timing requirements for each of those instances may be different. For some instances of the functional blocks, the inputs may be relatively far from the sender delaying signal propagation beyond a predetermined amount of time.

The amount of delay time is directly proportional to the distance between the sending and the receiving functional blocks, which defines a time and/or distance threshold. The distance and the time are related via signal propagation speed (Speed=Distance/Time), and hence there is a one-to-one correspondence between their values as disclosed herein. Any receiving functional block closer than the distance threshold may be labeled as a “near” functional block, and any that is farther than the distance threshold may be labeled as a “far” functional block. This delay can cause setup time failure. For near functional blocks, the signals can arrive at their inputs too early, and cause a race condition (output of a digital circuit is generated before the input arrives) or hold time violation. The time/distance threshold may be determined based on a combination of the distance between sending and receiving functional blocks and the setup and hold timing specification of the inputs to the functional blocks. The smaller the distance and the smaller the setup and hold time intervals, the smaller the distance/time threshold.

For far functional blocks, the signals can arrive too late and violate setup timing specifications. Therefore, it may be difficult to balance the trade-off between setup and hold timing constraints. For example, if a first functional block sends a signal, such as data, to a second and a third functional block, the signal may arrive at the receiving blocks at different times. This is due to propagation delay over a relatively longer distance, if the second functional block is closer to the sending functional block (first functional block) than the third functional block. These different timings of the signal arrival may cause a violation of setup and hold timing when the trigger edge of the clock signal arrives.

There are some approaches that may be employed to solve these problems, however, each approach has certain drawbacks. One approach is to split the connection routing such that wires that would logically be shared by a far and near instance are made different and specific to each distance. Now, delay may be added to the wire going to the near instance to delay the arrival of the input signal. For this approach to work, extra metal may be added to create different connection paths and buffers may be placed at the compositional level. However, this approach may not work for dense designs where a large number of functional blocks are laid out in close proximity of each other. Another approach may be to create multiple versions of the functional blocks, with one version made to have timing designed for a near instance and another version made to have timing designed for a far instance. This approach may also work, but it will take substantial time and effort to design multiple functional blocks instead of just one.

To solve this problem without the aforementioned drawbacks, another approach is disclosed herein. For a functional block, a dual port is created with two logical inputs. One input is labeled as “slow” and one as “fast”. These inputs are logically identical and carry the same data but have different timing requirements. Each input may have a certain amount of time delay due to circuit capacitance or other circuit elements, but the slow input may be given an additional delay component for the express purpose of creating a delay compared with the fast input. The delay component added to the slow input may be a buffer or other circuit element that creates a time delay in the path of a signal.

For near instances of functional blocks the slow input is used and connected to the data signal, while for far instances the fast input is used. The unused input in each instance is then tied off to a power rail of the circuit, disabling the unused input. The two slow and fast inputs of each functional block are logically OR'd together using a logic OR-gate, a wired-OR configuration, or other circuit element that is configured to behave as an OR-gate. In this OR'd configuration, either input, slow or fast, of the functional block may carry the input signal to the functional block, regardless of the other input.

With the described approach, the functional block only needs to be designed and built once with a single set of timing constraints on the inputs instead of designing and building several different functional block versions with different sets of timing constraints on the inputs. Moreover, the single set of timing constraints on the fast and slow inputs enable building the functional block with standard register logic synthesis and place-and-route flows.

A circuit often has two power rails, one at low voltage or ground, and one at a relatively higher voltage. The low-voltage rail is often designated as ground or voltage source supply (VSS). More than two power rails may exist in a circuit. The ports are physically placed on the functional blocks so that one signal or power rail wire can connect to either port. This arrangement has the advantage of not duplicating wires or adding the complexity of multiple versions of the same functional block.

Even though this disclosure describes the given solution with respect to one time/distance threshold defining two categories of functional blocks, the near and the far, the basic idea is directly applicable to multiple time/distance thresholds that define multiple categories of functional blocks. More specifically, N thresholds define N+1 categories. So, instead of only a near and far functional block types being defined, a first category (closest to the sender), a second category (next closest to the sender), a third category (next closest to the sender after the second category), and so on, may be defined. Accordingly, instead of having two inputs, slow and fast, corresponding to two categories of functional blocks, near and far, N+1 inputs are used, one for each category of functional blocks. These N+1 inputs will each have a different delay to accommodate the distance for each category. The appropriate input (with a delay corresponding to the distance of the functional block from sender) of the N+1 inputs is coupled with the data signal, while all other inputs are coupled to power rail or VSS to be disabled. The operation of the N+1 categories of functional blocks is substantially similar to the case of two categories as further described herein.

To address the setup and hold timing specifications of functional blocks, an ASIC is disclosed that is formed on a die with multiple functional blocks distributed on the die, each functional block being able to send and to receive data, and each having two inputs labeled slow and fast. The slow input may have a delay component that creates a delay in receiving a data signal, and the fast input may have less delay than the slow input. A switch may be used to couple the slow input and the fast input of a receiving functional block to a data signal based on a distance of the receiving functional block from a sending functional block.

Also disclosed is method of adjusting setup and hold timing, which includes determining whether one of a number of receiving functional blocks is in a near category and coupling a slow input of the receiving functional block to a signal data if the receiving functional block is in the near category, the slow input having an additional delay compared with a fast input of the receiving functional blocks.

Further disclosed is a functional block of an ASIC, the functional block having a slow input with a delay element that creates a delay in a receipt of a data signal at the slow input, and a fast input having less delay than the slow input. A logical OR-gate may be used to couple the slow input and the fast input together.

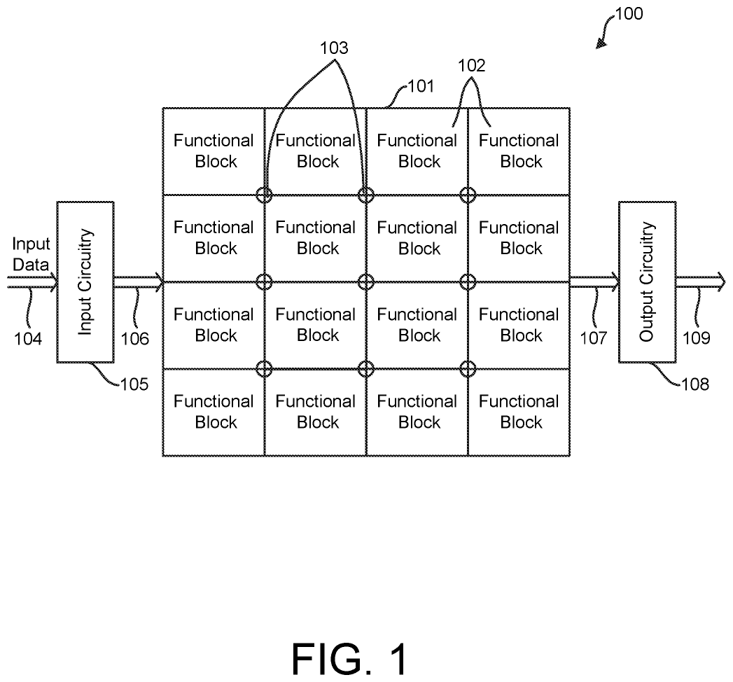

FIG. 1 is an ASIC computing environment 100 with multiple replicated functional blocks 102 and input circuitry 105 and an output circuitry 108 according to one or more examples of the disclosure. The ASIC computing environment 100 includes an ASIC 101, functional blocks (also called IP blocks) 102, switching elements 103, input data connection 104, input circuitry 105, ASIC input connection 106, ASIC output connection 107, output circuitry 108, and output data connection 109.

The ASIC computing environment 100 is arranged to provide a data interface for the ASIC 101. Generally, the input circuitry 105 and the output circuitry 108 are not on the same die as the ASIC. They may be placed as separate circuitry on a circuit board on which the ASIC is also located. The input circuitry may include signal filters, buffers, connectors for interfacing to other circuits and systems, and the like, to prepare the data signal for use by the ASIC. The output circuitry may include similar elements.

In an example implementation, the functional blocks 102, as noted above, are identical modules that perform the same functions and are distributed on the ASIC die. The functional blocks 102 may communicate with each other by sending data. The data are sent by a sending functional block 102 and be received at one of the other ones as the receiving functional. Each functional block 102 has one slow input and one fast input. These inputs are identical and can carry the same data but have different delays to meet their respective setup and hold timing specifications. Each input may have some amount of time delay due to circuit capacitance, data buffer, or for other reasons, but the slow input may be given an additional delay component for the express purpose of creating an additional delay compared with the fast input. The delay component added to the slow input may be a delay buffer or other circuit element that delays the signal, as further described herein.

The switching elements 103 can act as a multiplexer to connect the output of a sending functional block 102 to the appropriate input (slow or fast) of a receiving functional block 102, depending on the distance between the sending and the receiving functional blocks. Each functional block 102 may be both a sending functional block and a receiving functional block. The switching elements 103 may be arranged in a distributed grid, like a switching fabric, or as a different switching configuration such as a central switch, or a combination of both. In a distributed grid, each switching element 103 may act autonomously based on the functional blocks 102 layout on the ASIC die that is preprogrammed in the switch. Alternatively, the switching element 103 may be controlled in part by a central switching module (not shown) that provides the appropriate delay information based on the distance between the sending and the receiving functional blocks, but the actual switching is done by the switching elements 103 locally at the receiving functional blocks.

Regardless of the physical arrangement or architecture of the switching elements 103, one of their functions is to select the input with the appropriate delay (slow or fast) at a receiving functional block 102 and direct the input signal (data) to the selected input. This function is similar to a multiplexer in which one input may be directed to one of a number of outputs based on selection criteria. The selection criterion in this case, is the distance between the sending and the receiving functional blocks 102.

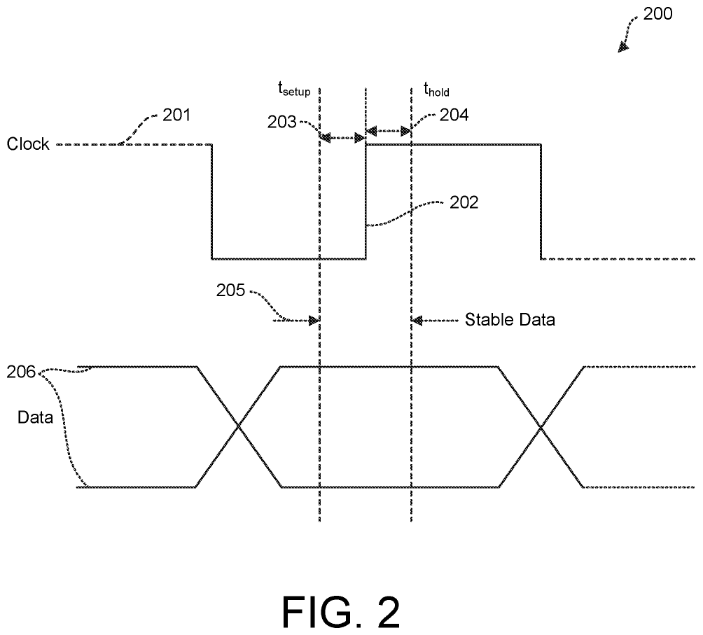

FIG. 2 depicts a timing diagram 200 showing setup time 203 and hold time 204 for a functional block of the ASIC of FIG. 1, according to one or more examples of the disclosure. The timing diagram 200 shows digital data forms against time on the horizontal axis. The digital include clock signal 201, setup time 203, hold time 204, trigger edge 202 of the clock signal, data stability time interval 205, and data signals 206.

Clock-driven digital circuits such as circuit stages, flipflops, registers, buffered inputs to functional modules and blocks, and the like, that work based on data stability. Clock signals 201 are generally a train of square waves with a fixed and regular frequency, sometimes referred to as operating frequency because most circuit operations are dependent on signal propagating through the circuit. One of the falling or rising edges of the clock signal 201 may be used as trigger edge to trigger a digital event. The digital event is generally data transfer from one stage in the circuit to the next.

Generally, the data signal propagates from one stage of the circuit to another on the trigger edge of the clock signal. Each stage of the signal propagation is finalized when the data output from the previous stage is latched or captured by the register or flip-flops (not shown) of the input of the next stage. For example, if the rising edge 202 is designed to be the trigger edge, then to latch the data signal 206 successfully, the data signal is not changed for at least the period of time equal to the sum of the setup time and the hold time (tₛₑₜᵤₚ+t_{hold}) around the trigger edge 202, so the data signal does not change in the middle of latching and give an undefined result.

With continued reference to FIG. 2, when an input data signal 206 arrives at a clocked input of a circuit stage from a previous circuit stage, the data signal is maintained without change for at least the data stability time interval 205. The cross-over of data signal 206 signifies the general condition of binary data change from low to high or from high to low. The trigger edge 202 is often not in the middle of the stable data stability time interval 205 because the setup and hold time are often not symmetrical and one is longer than the other. The clocked digital circuits are designed around timing diagrams such as the timing diagram 200 to provide the correct setup and hold time for the given type of components and clock frequency. The higher the clock frequency, the more critical and sensitive the setup and hold timing.

In a clocked digital circuit, a single clock frequency is often used for all circuit elements and modules that are participants in one higher level or bigger function of the whole circuit, than the specific functions of the individual modules or stages of the circuit. Sometimes, a high frequency source clock may be provided, which is subsequently divided down to provide slower clocking for various modules that operate at different frequencies. For example, if a circuit is designed for digital signal processing, one stage may be a counter, another stage may be an adder, another stage may be a multiplier, and the like. The data moves from one stage to the next on the same clock signal distributed throughout the circuit and arrives at each point of use substantially simultaneously. However, the data signal is not distributed the same way. The data signal may travel arbitrary distances within the circuit to get to its destination. The setup and hold timing for a given or predetermined circuit and a given clock frequency may be satisfied by adding delay to data inputs to adjust for different time delays due to travel time to different destinations.

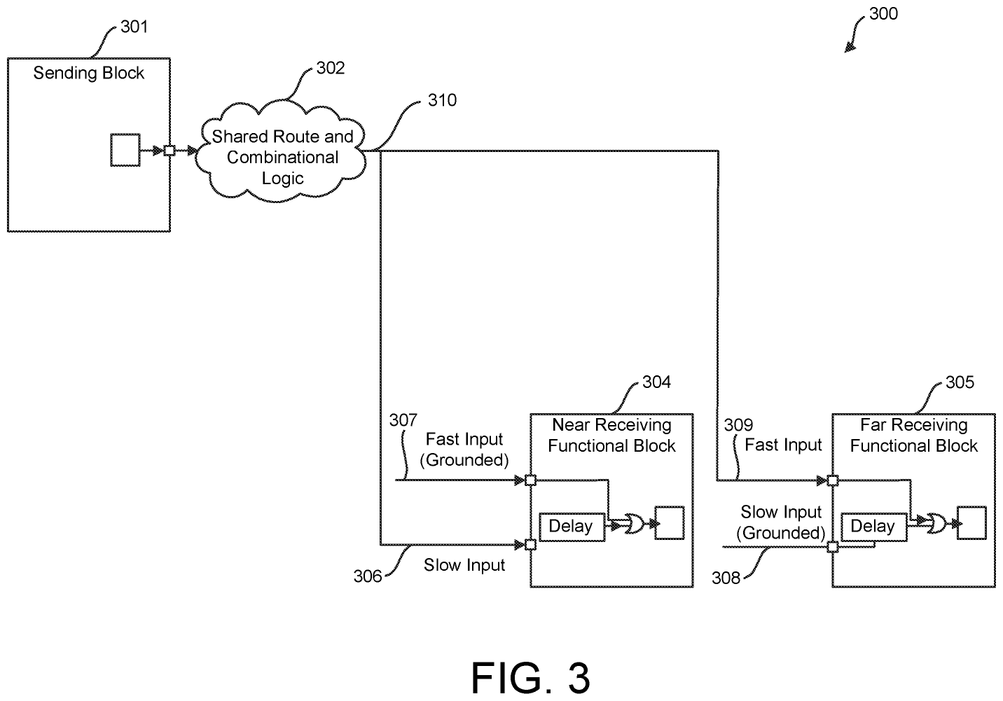

FIG. 3 depicts a subset 300 of the functional blocks of the ASIC of FIG. 1 sending and receiving data sending data signal 310 to other functional blocks of the ASIC, according to one or more examples of the disclosure. The subset 300 includes a sending block 301 sending data through a shared circuit route and combinational logic 302 to a near functional block 304 having a slow input (or port) 306 and a fast input 307, and sending the same data to a far functional block 305 having a slow input 308 and a fast input 309.

A clock signal, such as the clock signal 201 in FIG. 2, is distributed to all sending and receiving blocks to simultaneously clock all modules. The data signal 310 reaches the near functional block 304 earlier than the far functional block 305. To arrive at both the near and far functional blocks simultaneously, the near functional block 304 receives the data signal 310 on its slow input 306, while its other fast input 307 is tied to circuit ground to disable it by making it always OFF or disabled. Similarly, the far functional block 305 receives the data signal 310 on its fast input 309, while its other slow input 308 is tied to circuit ground to disable it by making it always OFF or disabled. So, in summary, the input data signal 310 is delayed for near the block to make up for the farther distance the data signal 310 has to travel to get to the far functional block 305, allowing the signal to get to both functional blocks simultaneously and meet their respective setup and hold timings.

Because the two inputs of each functional block 304 and 305 are logically OR'd together, only the signal value (logic high or low) received at the slow input 306 reaches the receiving near functional block 304. As noted earlier, two digital signals can be OR'd together using a logic OR-gate, a wired-OR configuration, or using any other technique or circuit element that functions as an OR between the two digital signals. For example, diodes and resistors may be used in a simple circuit to implement an OR function.

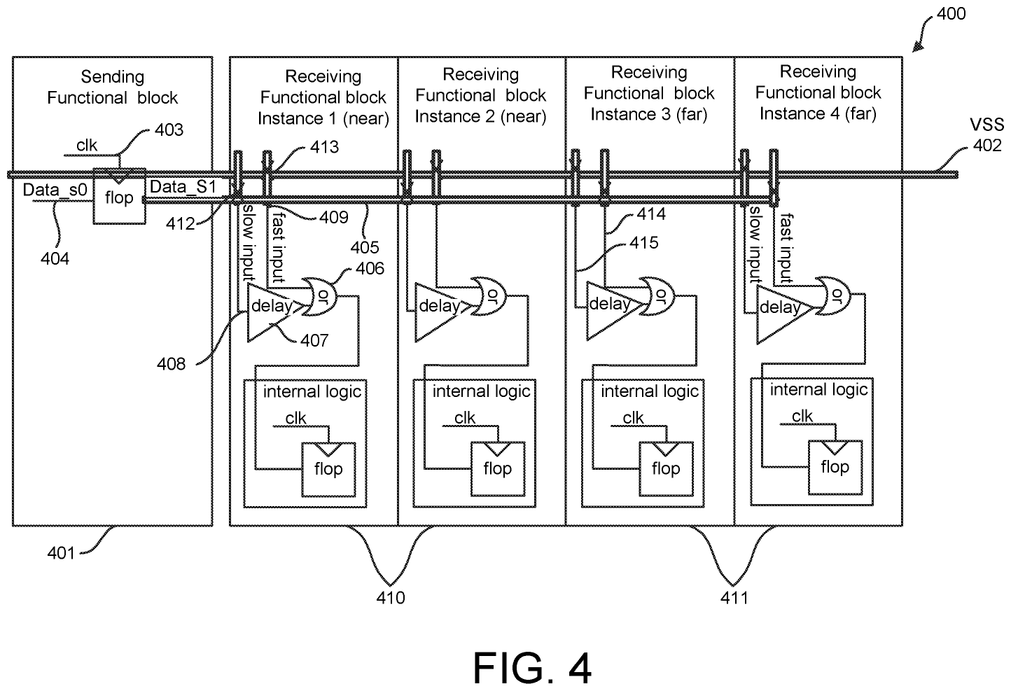

FIG. 4 depicts a connectivity configuration 400 of the multiple functional blocks of the ASIC of FIG. 1, according to one or more examples of the disclosure. The connectivity configuration includes a sending functional block (IP block) 401 with power rail (i.e., VSS) 402, clock signal 403, and incoming data signal 404 to sending functional block 401. The connectivity configuration further includes near receiving functional blocks 410 and far receiving functional blocks 411. The near receiving functional blocks 410 include a slow input 408 and fast input 409, the slow input 408 having a delay element 407 before connecting to an OR-gate 406 leading to the internal circuitry of the functional block. The slow input is coupled with the data signal 405 at connection point 412, and the fast input is connected to the power rail 402 at connection point 413. Similarly, the far receiving functional blocks 411 include a slow input 415 and fast input 414, the slow input 415 having a delay element before connecting to an OR-gate leading to the internal circuitry of the functional block. The fast input 414 is coupled with the data signal 405, and the slow input 415 is connected to the power rail 402.

As noted above, N+1 categories of functional blocks, each having N+1 inputs with varying delays may be used also if the number and distribution of the functional blocks on the ASIC die need N+1 categories due to larger distances on the die scale. In this case, the appropriate input with the appropriate delay for the category of the functional block is coupled with the data signal 405 and the rest of the inputs are tied to the power rail 402.

In this example implementation, the same clock signal 403 is applied to all functional blocks simultaneously to move the data forward from the sending functional block 410 to the receiving functional blocks 410 and 411. When the trigger edge 202 (see FIG. 2) of the clock signal arrives, the data signal 405 (similar to data signals 206 of FIG. 2) has to be stable at the input of the next clocked circuit stage to move without distortion or change of data value (from logic high to low or low to high) to the next circuit stage. This data stability is defined by meeting the setup and hold timing specifications with respect to the trigger edge 202. As the trigger edge 202 arrives at each of the near and far receiving functional blocks 410 and 411, respectively, the data signal 405 is delayed at the near receiving functional blocks 410 to arrive at the same time as the data signal 405 arrives at the far receiving functional blocks 411. This way, both the clock signal 403 and the data signal 405 are synchronized and arrive at the same time at both the near and the far receiving functional blocks 410 and 411, thus meeting the setup and hold specification at the input of each functional block. As such, the ASIC 101 and all its functional blocks 102 (see FIG. 1) operate without data errors due to violation of setup and hold timing.

With continued reference to FIG. 4, the switching elements 103 (see FIG. 1), not shown in this figure, configure the connections of the two or the several inputs to the receiving functional blocks 410 and 411 (similar to the functional blocks 102 of FIG. 1). The inputs are coupled by the switching elements 103, based on the category of the functional blocks corresponding with distance between sender and receiver, to either the data signal 405 or the VSS 402. The switching elements 103 perform such configuration based on the knowledge of the layout of the receiving functional blocks 410 and 411 and the distance between a given sending functional block and a receiving functional block. If the receiving functional block is in a near category, the its slow input is coupled with the data signal 405 and the other input (or other inputs, in the case of N+1 categories) are tied to the VSS 402 to disable it. If the receiving functional block is in the far category, then its fast input is coupled with the data signal 404 and the other input (or inputs) are coupled with the VSS 402 to disable it. Similarly, for the case of N+1 categories of functional blocks, the appropriate input is coupled with the data signal 405 and the rest of the inputs are coupled with the VSS 402.

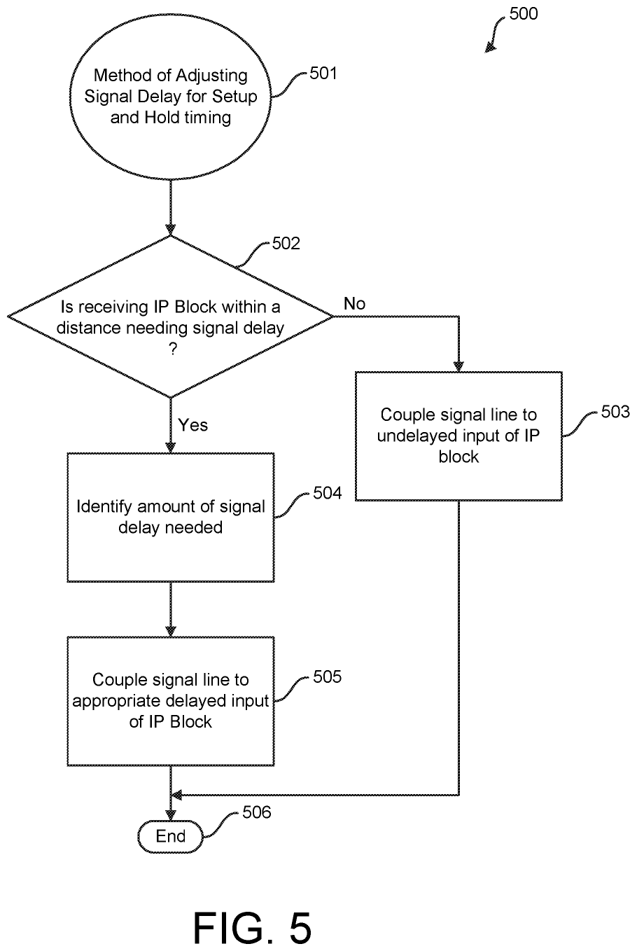

FIG. 5 is a flowchart 500 depicting a method of adjusting signal delay for setup and hold timing for the multiple functional blocks 102 of the ASIC of FIG. 1, according to one or more examples of the disclosure.

The method starts at block 501 and proceeds to the decision block 502. For a two-category configuration, when a sending functional block sends data to a receiving functional block, ascertain whether the receiving functional block is at distance less than a predetermined time and/or distance threshold from the sending functional block. If true, then proceed to block 504, otherwise proceed to block 503. For an (N+1)-category configurations, additional decision blocks (not shown), like block 502, are used, one for each category, to determine which category a receiving functional block belongs to. These additional decision blocks use the appropriate additional time/distance thresholds to determine whether the receiving functional block belongs to a particular category.

At block 503, it has been determined that the receiving functional block is in a far category, and hence, the fast (undelayed or less delayed) input of the receiving functional block is coupled with the data signal and the other input is coupled with the VSS to disable it. Proceed to block 506 and terminate the process.

At block 504, in the case of a two-category configuration, the functional block is in a near category, but in the case of an N+1 category configuration, the amount of delay needed is determined to identify the appropriate input for coupling with the data signal. The process proceeds to block 505.

At block 505, it has been determined what category the receiving functional block is in, and hence, the slow (delayed) input, for a two-category configuration, or the input with the appropriate delay, for an N+1 category configuration, of the receiving functional block is coupled with the data signal and the other input(s) is (are) coupled with the VSS to disable it. The process proceeds to block 506 and terminates.

The foregoing description, for purposes of explanation, used specific nomenclature to provide a thorough understanding of the disclosure. However, it will be apparent to one skilled in the art that the specific details are not required in order to practice the systems and methods described herein. The foregoing descriptions of specific examples are presented for purposes of illustration and description. They are not intended to be exhaustive of or to limit this disclosure to the precise forms described. Obviously, many modifications and variations are possible in view of the above teachings. The examples are shown and described in order to best explain the principles of this disclosure and practical applications, to thereby enable others skilled in the art to best utilize this disclosure and various examples with various modifications as are suited to the particular use contemplated. It is intended that the scope of this disclosure be defined by the claims and their equivalents below.

This concludes the detailed description. The particular embodiments disclosed above are illustrative only, as examples described herein may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the appended claims. Accordingly, the protection sought herein is as set forth in the claims below.

1. An application-specific integrated circuit (ASIC) comprising:
a plurality of functional blocks including a receiving functional block and a sending functional bock distributed on the ASIC, each of the plurality of functional blocks to send and to receive data, and each of the plurality of the functional blocks having a slow input port and a fast input port, the slow input port having a delay component that creates a delay in receiving a data signal, and the fast input port having less delay than the slow input port; and
a switch coupling the slow input port and the fast input port of the receiving functional block to a data signal based on a time delay between the receiving functional block and the sending functional block.

2. The ASIC of claim 1, the switch coupling the slow input port to the data signal if the receiving functional block is at a physical distance from the sending functional block that is less than a corresponding predetermined time threshold.

3. The ASIC of claim 1, further comprising a power rail to which the fast input port is coupled by the switch to disable the fast input port.

4. The ASIC of claim 2, the switch coupling the fast input port to the data signal if the receiving functional block is at a time delay from the sending functional block that is greater than the predetermined time threshold.

5. The ASIC of claim 1, the slow input port and the fast input port being coupled to each other via a logical OR-gate.

6. The ASIC of claim 2, the predetermined time threshold corresponding to a distance threshold based on a signal propagation speed.

7. The ASIC of claim 1, the switch being one of a switching element in a distributed switching configuration and a central switch.

8. The ASIC of claim 2, the predetermined time threshold being determined based on a setup and hold timing of the inputs to the plurality of functional blocks.

9. The ASIC of claim 1, the plurality of the functional blocks being identical.

10. A method of adjusting setup and hold timing, the method comprising:
determining whether one of a plurality of receiving functional blocks is in a near category; and
coupling a slow input port of the one of the plurality of receiving functional blocks to a signal data if the one of the plurality of receiving functional blocks in the near category, the slow input port having an additional delay compared with a fast input port of the one of the plurality of receiving functional blocks.

11. The method of claim 10, further comprising coupling the fast input port to a power rail of the ASIC to disable the fast input port.

12. The method of claim 10, further comprising determining whether one of a plurality of receiving functional blocks is in a far category.

13. The method of claim 10, determining whether one of a plurality of receiving functional blocks is in a near category comprising comparing a distance of the one of the plurality of receiving functional blocks and a sending functional block with a predetermined distance threshold.

14. The method of claim 10, the slow input port and the fast input port being logically OR'd together.

15. The method of claim 10, further comprising coupling the fast input port of the one of the plurality of receiving functional blocks to a power rail of the ASIC.

16. The method of claim 13, the predetermined distance threshold being based on a setup and hold timing of the one of the plurality of receiving functional blocks.

17. A dual port functional block included in an application-specific integrated circuit (ASIC), the dual port functional block comprising:
a slow input port having a delay element that creates a delay in a receipt of a data signal at the slow input port;
a fast input port having less delay than the slow input port; and
a logical OR circuit coupling the slow input port and the fast input port together to deliver the data signal to the dual port functional circuit block, the slow input port being coupled with the data signal and the fast input port being coupled with a circuit power rail, if the dual port functional block is within a predetermined time threshold from a source of the data signal.

18. The dual port functional block of claim 17, the delay in the slow input port being determined based on a time delay corresponding to a physical distance of the dual port functional block to other dual port functional blocks on the ASIC.

19. The dual port functional block of claim 17, the ASIC including a plurality of identical dual port functional blocks.

20. The dual port functional block of claim 19, the slow input port being coupled with the circuit power rail and the fast input port being coupled with the data signal, if the dual port functional block is at a greater time difference than the predetermined time threshold from the source of the data signal.
